(19) United States
(12) Patent Application Publication
(10) Pub. No.: US 2026/0146153 A1
(43) Pub. Date: May 28, 2026

(54) RESIN COMPOSITION FOR MOLDING AND ELECTRONIC COMPONENT DEVICE

(71) Applicant: RESONAC CORPORATION, Tokyo (JP)

(72) Inventors: Mika TANAKA, Minato-ku, Tokyo (JP); Yuma TAKEUCHI, Minato-ku, Tokyo (JP); Yuta SUKEGAWA, Minato-ku, Tokyo (JP); Shintaro OKADA, Minato-ku, Tokyo (JP)

(73) Assignee: RESONAC CORPORATION, Tokyo (JP)

(21) Appl. No.: 18/861,576

(22) PCT Filed: Nov. 21, 2023
(86) PCT No.: PCT/JP2023/041787

§ 371 Date: Oct. 29, 2024

(30) Foreign Application Priority Data
Nov. 22, 2022 (JP) 2022-186881

(51) Int. Cl. C08L 63/04; B29C 45/02; B29C 45/77; B29K 63/00; B29K 67/00; B29L 31/26; B29L 31/34; C08K 3/22; C08K 3/36; C08K 3/38; C08L 67/06

(52) U.S. Cl. CPC C08L 63/04; B29C 45/02; B29C 45/77; C08K 3/22; C08K 3/36; C08K 3/38; C08L 67/06; B29K 2063/00; B29K 2067/06; B29L 2031/26; B29L 2031/3456; C08K 2003/2227; C08K 2003/385

(57) ABSTRACT

A resin composition for molding includes: an epoxy resin containing at least one of a phenol novolac type epoxy resin with an epoxy equivalent of 156 g/eq to 250 g/eq and a cresol novolac type epoxy resin with an epoxy equivalent of 156 g/eq to 250 g/eq; an active ester compound; and an inorganic filler.

### TECHNICAL FIELD

The disclosure relates to a resin composition for molding and an electronic component device.

### RELATED ART

In response to demands for advancement in functionality and miniaturization of electronic devices in recent years, high-density integration, and further, high-density mounting, of electronic components have been progressing, and semiconductor packages used in such electronic devices are increasing and becoming smaller than ever before. Furthermore, radio waves used for communication in electronic devices are also becoming higher in frequency.

For example, Patent Document 1 and Patent Document 2 disclose thermosetting resin compositions including active ester resins as curing agents for an epoxy resin, which are said to be capable of suppressing a dielectric loss tangent of a cured product to a low level.
Patent Document 1: Japanese Patent Application Laid-Open No. 2012-246367
Patent Document 2: Japanese Patent Application Laid-Open No. 2014-114352

### SUMMARY OF INVENTION

### Problem to be Solved by Invention

Examples of a material for sealing electronic components such as semiconductor elements include a resin composition for molding including an epoxy resin, a curing agent, and an inorganic filler. With a material of a high dielectric loss tangent used as the above resin composition for molding, a transmission signal is converted to heat due to dielectric loss, and communication efficiency tends to decrease. Herein, an amount of dielectric loss generated due to heat conversion of radio waves emitted for communication in a dielectric is expressed as a product of a frequency, a square root of a relative permittivity, and a dielectric loss tangent. The transmission signal becomes easily converted to heat in proportion to the frequency. Particularly in recent years, to accommodate an increase in the number of channels and the like accompanying diversification of information, the radio waves used for communication have become higher in frequency. From the viewpoint of reducing dielectric loss, a resin composition for molding capable of molding a cured product with a low dielectric loss tangent is required.

On the other hand, with an active ester resin used as a curing agent for suppressing the dielectric loss tangent of the cured product to a low level, a strength of the cured product may decrease.

The disclosure has been made in view of the above conventional circumstances, and an objective thereof is to provide a resin composition for molding capable of forming a cured product that exhibits a low dielectric loss tangent and is excellent in strength, and an electronic component device using the same.

### Means for Solving Problem

Specific means for achieving the above objective are as follows.

<1> A resin composition for molding including: an epoxy resin containing at least one of a phenol novolac type epoxy resin with an epoxy equivalent of 156 g/eq to 250 g/eq and a cresol novolac type epoxy resin with an epoxy equivalent of 156 g/eq to 250 g/eq; an active ester compound; and an inorganic filler.

<2> The resin composition for molding according to <1>, including, as the epoxy resin and the active ester compound, a combination in which an unreacted epoxy ratio becomes 2% or less.

<3> The resin composition for molding according to <1> or <2>, in which a content ratio of an entirety of the inorganic filler exceeds 50 volume % with respect to an entirety of the resin composition for molding.

<4> The resin composition for molding according to any one of <1> to <3>, which is used for a high-frequency device.

<5> The resin composition for molding according to <4>, which is used for sealing an electronic component in the high-frequency device.

<6> The resin composition for molding according to <4>, which is used for an Antenna-in-Package.

<7> An electronic component device including:
a supporting member;
an electronic component disposed on the supporting member; and
a cured product of the resin composition for molding according to any one of <1> to <3>, which seals the electronic component.

<8> The electronic component device according to <7>, in which the electronic component includes an antenna.

### Effects of Invention

According to the disclosure, it is possible to provide a resin composition for molding capable of forming a cured product that exhibits a low dielectric loss tangent and is excellent in strength, and an electronic component device using the same.

### DESCRIPTION OF EMBODIMENTS

Hereinafter, embodiments of the disclosure will be described in detail. However, the disclosure is not limited to the following embodiments. In the following embodiments, constituent elements thereof (including element steps and the like) are not necessarily required unless explicitly stated. The same applies to numerical values and ranges thereof, which do not limit the disclosure.

In the disclosure, the term “process” includes not only a process that is independent of other processes, but also a process that cannot be clearly distinguished from other processes as long as the purpose of the process is achieved.

In the disclosure, a numerical range indicated using “A to B” includes numerical values described before and after “to” as a minimum value and a maximum value, respectively.

In numerical ranges described in stages in the disclosure, an upper limit value or a lower limit value described in one numerical range may be replaced with an upper limit value or a lower limit value of another numerical range described in stages. Further, in the numerical ranges described in the disclosure, the upper limit value or the lower limit value of the numerical range may be replaced with a value shown in Examples.

In the disclosure, each component may include multiple types of corresponding substances. In the case where multiple types of substances corresponding to each component are present in a composition, unless otherwise specified, a content ratio or a content of each component refers to a total content ratio or content of the multiple types of substances present in the composition.

In the disclosure, a particle corresponding to each component may include multiple types of particles. In the case where multiple types of particles corresponding to each component are present in a composition, unless otherwise specified, a particle diameter of each component refers to a value for a mixture of the multiple types of particles present in the composition.

### <Resin Composition for Molding>

A resin composition for molding of the disclosure includes an epoxy resin, an active ester compound, and an inorganic filler, the epoxy resin including at least one of a phenol novolac type epoxy resin with an epoxy equivalent of 156 g/eq to 250 g/eq and a cresol novolac type epoxy resin with an epoxy equivalent of 156 g/eq to 250 g/eq. Hereinafter, the phenol novolac type epoxy resin with an epoxy equivalent of 156 g/eq to 250 g/eq and the cresol novolac type epoxy resin with an epoxy equivalent of 156 g/eq to 250 g/eq may be referred to as specific novolac type epoxy resins.

The resin composition for molding of the disclosure is capable of forming a cured product that exhibits a low dielectric loss tangent and is excellent in strength. Although the reason thereof is not clear, it is inferred to be as follows.

In the case where a phenol curing agent, for example, is used as the curing agent of the epoxy resin, secondary hydroxyl groups are generated in the reaction between the epoxy resin and the phenol curing agent. In contrast, in the case where an active ester compound is used as the curing agent of the epoxy resin, ester groups are formed instead of secondary hydroxyl groups in the reaction between the epoxy resin and the active ester compound. Since ester groups have a lower polarity compared to secondary hydroxyl groups, it is inferred that a resin composition for molding including an active ester compound as a curing agent can suppress the dielectric loss tangent of the cured product to a lower level compared to a resin composition for molding including only a curing agent that generates secondary hydroxyl groups as the curing agent.

Further, polar groups in the cured product increase water absorption of the cured product. By using an active ester compound as the curing agent, a concentration of polar groups in the cured product can be suppressed, and water absorption of the cured product can be suppressed. It is inferred that by suppressing water absorption of the cured product, i.e., by suppressing a content of H₂O, which is a polar molecule, the dielectric loss tangent of the cured product can be further suppressed to a lower level.

Further, since the specific novolac type epoxy resin has few molecular structures in the molecule thereof that may cause steric hindrance, a crosslink density of the cured product can be improved. Thus, it is inferred that a cured product excellent in strength may be formed. Furthermore, with little steric hindrance in the molecule, since unreacted epoxy groups are less likely to remain in the cured product, unreacted epoxy groups, which have a high polarity, are less likely to remain in the cured product, and it is inferred that the dielectric loss tangent of the cured product can be suppressed to a low level.

Based on the above, it is inferred that the resin composition for molding of the disclosure is capable of forming a cured product that exhibits a low dielectric loss tangent and is excellent in strength.

Hereinafter, each component constituting the resin composition for molding will be described. The resin composition for molding of the disclosure contains at least one of specific novolac type epoxy resins as an epoxy resin, an active ester compound as a curing agent, and an inorganic filler, and may include other components as necessary.

### (Epoxy Resin)

The resin composition for molding of the disclosure includes at least one of specific novolac type epoxy resins as the epoxy resin. The resin composition for molding of the disclosure may also include another epoxy resin other than the specific novolac type epoxy resins.

In the case where the resin composition for molding of the disclosure includes the another epoxy resin, a ratio of a total of the specific novolac type epoxy resins in the epoxy resin is preferably 50 mass % to 95 mass %, more preferably 60 mass % to 90 mass %, and even more preferably 70 mass % to 80 mass %.

From the viewpoint of strength, flowability, heat resistance, moldability, etc., a mass ratio of the epoxy resin in an entirety of the resin composition for molding is preferably 0.5 mass % to 30 mass %, more preferably 2 mass % to 20 mass %, and even more preferably 3.5 mass % to 13 mass %.

The specific novolac type epoxy resin is not particularly limited as long as it is an epoxy resin with an epoxy equivalent of 156 g/eq to 250 g/eq obtained by epoxidizing a phenol novolac resin or a cresol novolac resin using methods such as glycidyl etherification. An epoxy equivalent of the specific novolac type epoxy resin is preferably 170 g/eq to 240 g/eq, more preferably 180 g/eq to 230 g/eq, and even more preferably 190 g/eq to 220 g/eq.

As the specific novolac type epoxy resin, epoxy resins represented by General Formula (B) below are more preferable. Among the epoxy resins represented by General Formula (B) below, ESCN-190 and ESCN-195 (product names, manufactured by Sumitomo Chemical Co., Ltd.) in which R^{A} is a methyl group, and N-770 and N-775 (product names, manufactured by DIC Corporation) in which R^{A} is a hydrogen atom are commercially available.

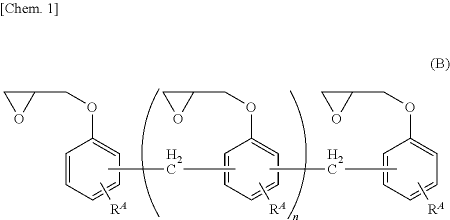

In Formula (B), R^{A} represents a hydrogen atom or a methyl group. n is an average value and represents a number from 0 to 10.

A type of the another epoxy resin is not particularly limited as long as it includes an epoxy group in the molecule.

Specific examples of the another epoxy resin includes: novolac type epoxy resins (excluding the specific novolac type epoxy resins) obtained by epoxidizing novolac resins produced by condensation or co-condensation, under acidic catalysis, of at least one phenolic compound selected from the group consisting of phenol compounds such as phenol, cresol, xylenol, resorcinol, catechol, bisphenol A, bisphenol F, etc., and naphthol compounds such as α-naphthol, β-naphthol, dihydroxynaphthalene, etc., with aliphatic aldehyde compounds such as formaldehyde, acetaldehyde, propionaldehyde, etc.; triphenylmethane type epoxy resins obtained by epoxidizing triphenylmethane type phenol resins produced by condensation or co-condensation, under acidic catalysis, of the above phenolic compounds with aromatic aldehyde compounds such as benzaldehyde, salicylaldehyde, etc.; copolymer type epoxy resins obtained by epoxidizing novolac resins produced by co-condensation, under acidic catalysis, of the above phenol compounds and naphthol compounds with aldehyde compounds; diphenylmethane type epoxy resins which are diglycidyl ethers of bisphenol A, bisphenol F, etc.; biphenyl type epoxy resins which are diglycidyl ethers of alkyl-substituted or unsubstituted biphenols; stilbene type epoxy resins which are diglycidyl ethers of stilbene-based phenol compounds; sulfur atom-containing epoxy resins which are diglycidyl ethers of bisphenol S and the like; epoxy resins which are glycidyl ethers of alcohols such as butanediol, polyethylene glycol, polypropylene glycol, etc.; glycidyl ester type epoxy resins which are glycidyl esters of polyvalent carboxylic acid compounds such as phthalic acid, isophthalic acid, tetrahydrophthalic acid, etc.; glycidylamine type epoxy resins in which active hydrogen bonded to nitrogen atoms of aniline, diaminodiphenylmethane, isocyanuric acid, etc. is replaced with glycidyl groups; dicyclopentadiene type epoxy resins obtained by epoxidizing co-condensation resins of dicyclopentadiene and phenol compounds; alicyclic epoxy resins such as vinylcyclohexene diepoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane, etc., in which olefin bonds in the molecule are epoxidized; paraxylylene-modified epoxy resins which are glycidyl ethers of paraxylylene-modified phenol resins; metaxylylene-modified epoxy resins which are glycidyl ethers of metaxylylene-modified phenol resins; terpene-modified epoxy resins which are glycidyl ethers of terpene-modified phenol resins; dicyclopentadiene-modified epoxy resins which are glycidyl ethers of dicyclopentadiene-modified phenol resins; cyclopentadiene-modified epoxy resins which are glycidyl ethers of cyclopentadiene-modified phenol resins; polycyclic aromatic ring-modified epoxy resins which are glycidyl ethers of polycyclic aromatic ring-modified phenol resins; naphthalene type epoxy resins which are glycidyl ethers of naphthalene ring-containing phenol resins; halogenated phenol novolac type epoxy resins; hydroquinone type epoxy resins; trimethylolpropane type epoxy resins; linear aliphatic epoxy resins obtained by oxidizing olefin bonds with peracids such as peracetic acid; aralkyl type epoxy resins obtained by epoxidizing aralkyl type phenol resins such as phenol aralkyl resins, naphthol aralkyl resins, etc. Furthermore, examples of the epoxy resin also include epoxidized acrylic resins and the like. The another epoxy resin may be used as one type alone or used as a combination of two or more types.

The another epoxy resin preferably includes a biphenyl type epoxy resin.

An epoxy equivalent (molecular weight/number of epoxy groups) of the another epoxy resin is not particularly limited. From the viewpoint of balancing various properties such as moldability, reflow resistance, electrical reliability, etc., the epoxy equivalent of the another epoxy resin is preferably 100 g/eq to 1000 g/eq, and more preferably 150 g/eq to 500 g/eq.

In the disclosure, the epoxy equivalent of the epoxy resin is a value measured according to a method conforming to JIS K 7236:2009.

In the case where the epoxy resin is solid, a softening point or a melting point of the epoxy resin is not particularly limited. The softening point or the melting point of the epoxy resin is preferably 40° C. to 180° C. from the viewpoint of moldability and reflow resistance, and is more preferably 50° C. to 130° C. from the viewpoint of handling during preparation of the resin composition for molding.

The melting point or the softening point of the epoxy resin is a value measured according to differential scanning calorimetry (DSC) or according to a method (ring and ball method) conforming to JIS K 7234:1986.

### (Curing Agent)

The resin composition for molding of the disclosure includes an active ester compound as a curing agent. The curing agent may include another curing agent other than the active ester compound, such as phenol curing agents.

The resin composition for molding may include only one type of active ester compound or may include two or more types.

### —Active Ester Compound—

Herein, the active ester compound refers to a compound that includes, in one molecule, one or more ester groups that react with epoxy groups, and has an effect of curing the epoxy resin.

A type of the active ester compound is not particularly limited as long as the active ester compound is a compound that includes, in the molecule, one or more ester groups that react with epoxy groups. Examples of the active ester compound include phenol ester compounds, thiophenol ester compounds, N-hydroxyamine ester compounds, esterified heterocyclic hydroxy compounds, etc.

Examples of the active ester compound include ester compounds obtained from at least one of aliphatic carboxylic acids and aromatic carboxylic acids, and at least one of aliphatic hydroxy compounds and aromatic hydroxy compounds. Ester compounds that take aliphatic compounds as components of polycondensation tend to be excellent in compatibility with epoxy resins due to the aliphatic chains included. Ester compounds that take aromatic compounds as components of polycondensation tend to be excellent in heat resistance due to the aromatic rings included.

Specific examples of the active ester compound include aromatic esters obtained by condensation reactions between aromatic carboxylic acids and phenolic hydroxyl groups. Specifically, aromatic esters obtained by condensation reactions between aromatic carboxylic acids and phenolic hydroxyl groups are preferable, taking a mixture of the following as raw materials: an aromatic carboxylic acid component in which 2 to 4 hydrogen atoms of aromatic rings such as benzene, naphthalene, biphenyl, diphenylpropane, diphenylmethane, diphenyl ether, diphenylsulfonic acid, etc. are replaced with carboxyl groups; a monovalent phenol in which 1 hydrogen atom of the above aromatic ring is replaced with a hydroxyl group; and a polyvalent phenol in which 2 to 4 hydrogen atoms of the above aromatic ring are replaced with hydroxyl groups. In other words, aromatic esters including structural units derived from the above aromatic carboxylic acid component, structural units derived from the above monovalent phenol, and structural units derived from the above polyvalent phenol are preferable.

Specific examples of the active ester compound include active ester resins having a structure obtained by reacting a phenolic resin having a molecular structure in which phenol compounds are linked via an alicyclic hydrocarbon group, an aromatic dicarboxylic acid or a halide thereof, and an aromatic monohydroxy compound, as described in Japanese Patent Application Laid-Open No. 2012-246367. As such active ester resins, compounds represented by Structural Formula (1) below are preferable.

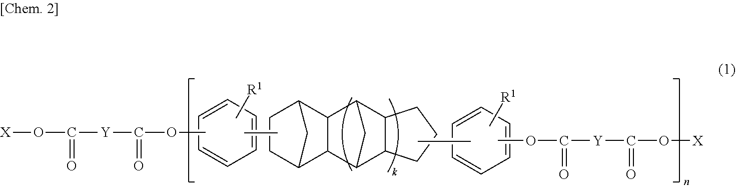

In Structural Formula (1), R¹ is a hydrogen atom, an alkyl group having 1 to 4 carbon atoms, or a phenyl group; X is an unsubstituted benzene ring, an unsubstituted naphthalene ring, a benzene ring or a naphthalene ring replaced with an alkyl group having 1 to 4 carbon atoms, or a biphenyl group; Y is a benzene ring, a naphthalene ring, or a benzene ring or a naphthalene ring replaced with an alkyl group having 1 to 4 carbon atoms; k is 0 or 1; and n represents an average number of repetitions and is 0 to 5.

Specific examples of compounds represented by Structural Formula (1) include Exemplary Compounds (1-1) to (1-10) below. In the structural formulas, t-Bu represents a tert-butyl group.

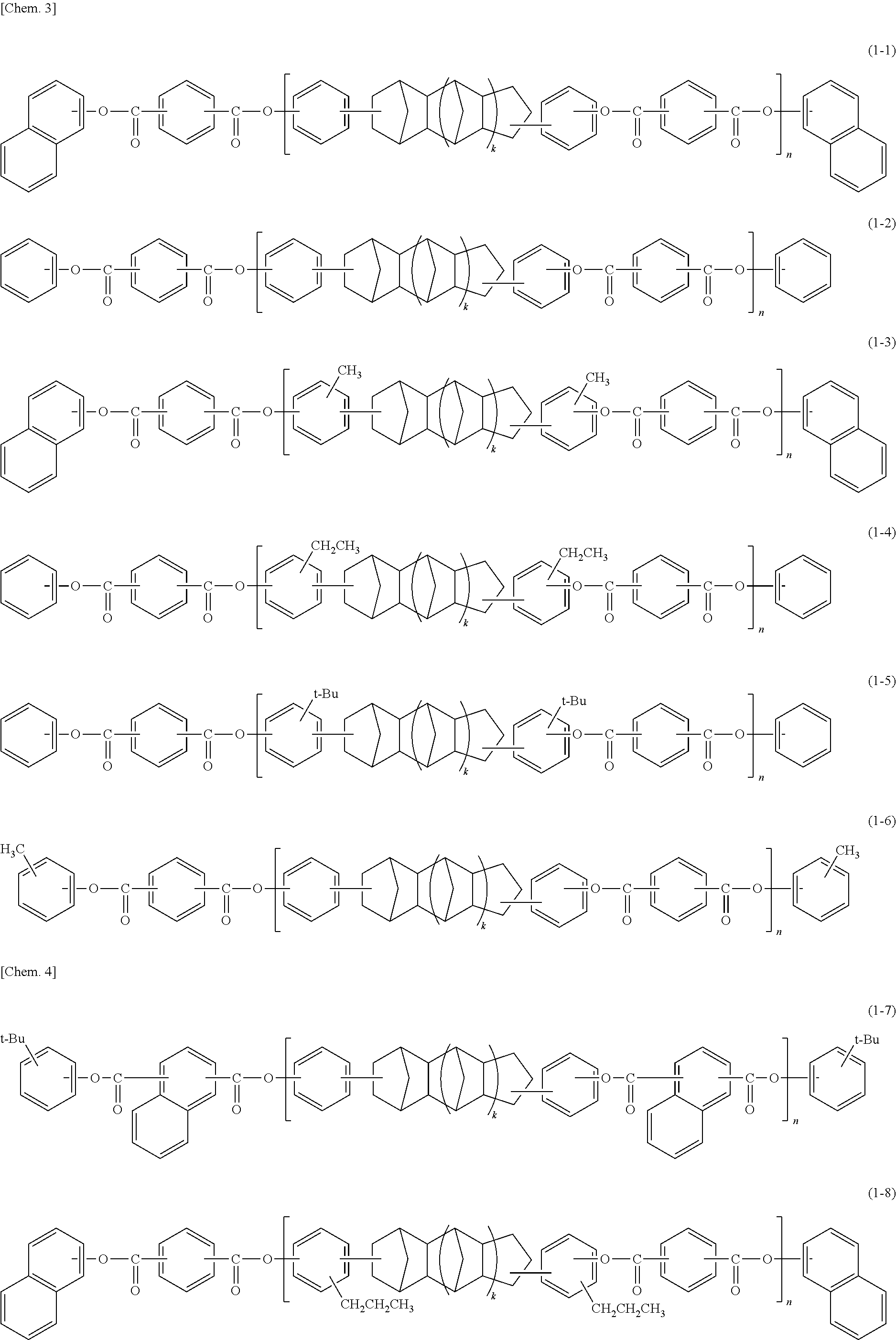

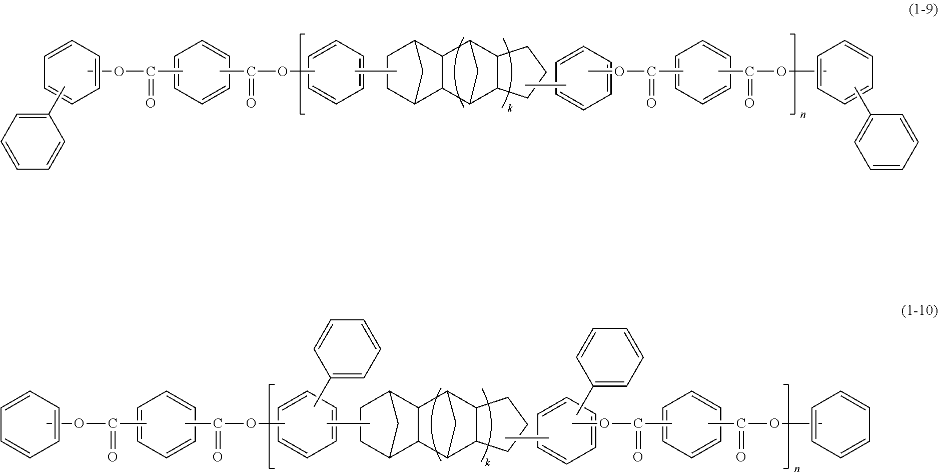

Other specific examples of the active ester compound include compounds represented by Structural Formula (2) below and compounds represented by Structural Formula (3) below, as described in Japanese Patent Application Laid-Open No. 2014-114352.

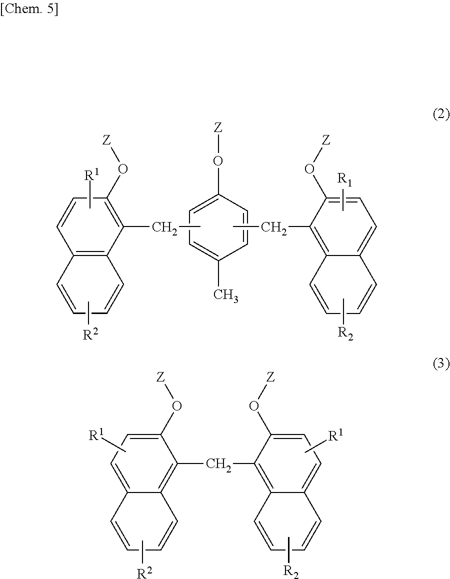

In Structural Formula (2), R¹ and R² are each independently a hydrogen atom, an alkyl group having 1 to 4 carbon atoms, or an alkoxy group having 1 to 4 carbon atoms; Z is an ester-forming structural moiety (z1) selected from the group consisting of an unsubstituted benzoyl group, an unsubstituted naphthoyl group, a benzoyl group or a naphthoyl group replaced with an alkyl group having 1 to 4 carbon atoms, and an acyl group having 2 to 6 carbon atoms, or a hydrogen atom (z2); and at least one Z is the ester-forming structural moiety (z1).

In Structural Formula (3), R¹ and R² are each independently a hydrogen atom, an alkyl group having 1 to 4 carbon atoms, or an alkoxy group having 1 to 4 carbon atoms; Z is an ester-forming structural moiety (z1) selected from the group consisting of an unsubstituted benzoyl group, an unsubstituted naphthoyl group, a benzoyl group or a naphthoyl group replaced with an alkyl group having 1 to 4 carbon atoms, and an acyl group having 2 to 6 carbon atoms, or a hydrogen atom (z2); and at least one Z is the ester-forming structural moiety (z1).

Specific examples of compounds represented by Structural Formula (2) include Exemplary Compounds (2-1) to (2-6) below.

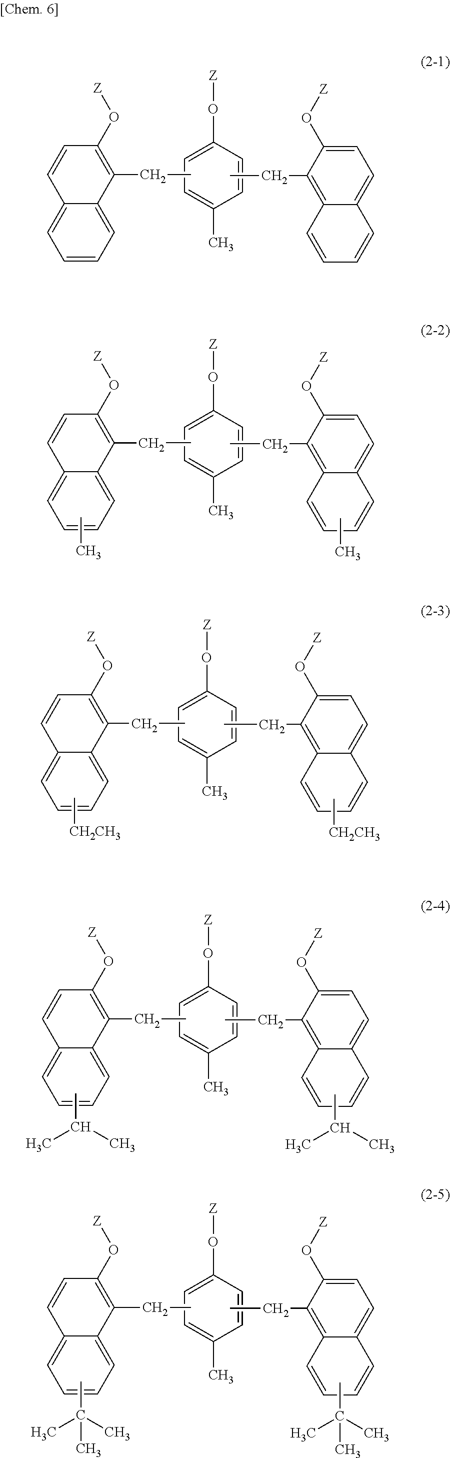

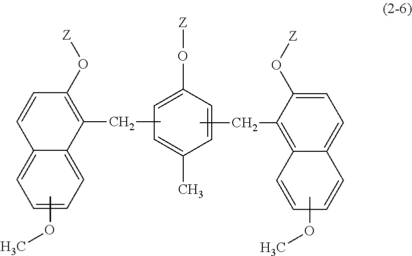

Specific examples of compounds represented by Structural Formula (3) include Exemplary Compounds (3-1) to (3-6) below.

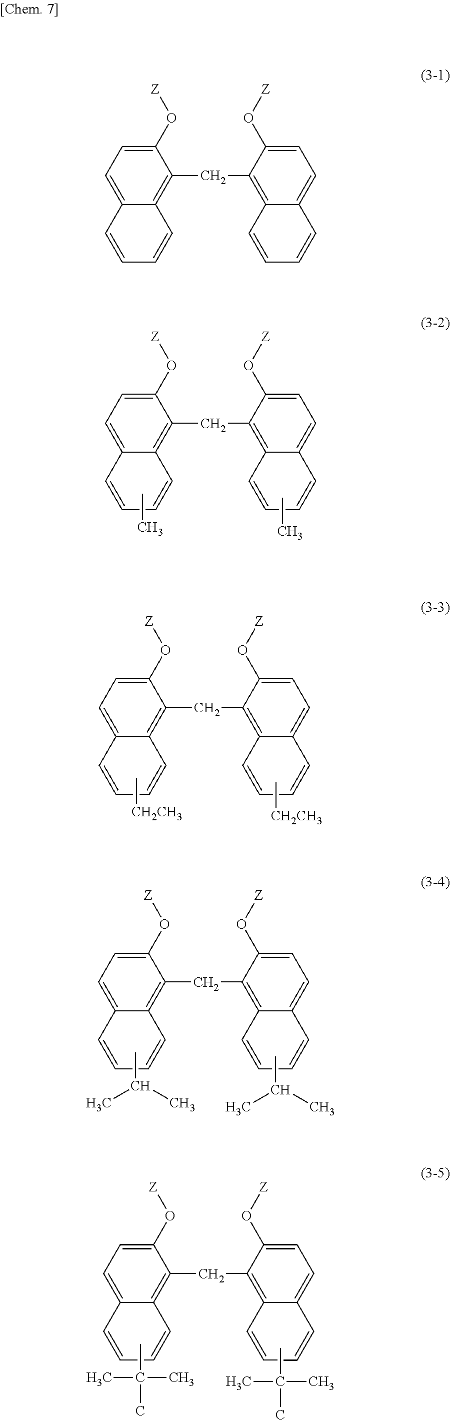

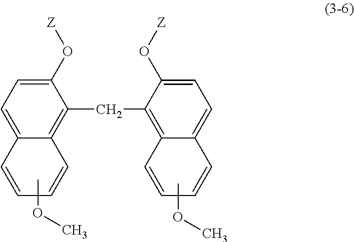

Commercially available products may be used as the active ester compound. Examples of commercially available products of the active ester compound include: “EXB9451”, “EXB9460”, “EXB9460S”, and “HPC-8000-65T” (manufactured by DIC Corporation) as active ester compounds including a dicyclopentadiene type diphenol structure; “EXB9416-70BK”, “EXB-8”, and “EXB-9425” (manufactured by DIC Corporation) as active ester compounds including an aromatic structure; “DC808” (manufactured by Mitsubishi Chemical Corporation) as an active ester compound including an acetylated product of phenol novolac; “YLH1026” (manufactured by Mitsubishi Chemical Corporation) as an active ester compound including a benzoylated product of phenol novolac; etc.

An ester equivalent (molecular weight/number of ester groups) of the active ester compound is not particularly limited. From the viewpoint of balancing various properties such as moldability, reflow resistance, electrical reliability, etc., a range of 150 g/eq to 400 g/eq is preferable, a range of 170 g/eq to 300 g/eq is more preferable, and a range of 200 g/eq to 250 g/eq is even more preferable.

The ester equivalent of the active ester compound is a value measured according to a method conforming to JIS K 0070:1992.

To further improve the strength of the cured product, the resin composition for molding of the disclosure preferably includes, as the epoxy resin and the active ester compound, a combination in which an unreacted epoxy ratio becomes 2% or less, more preferably a combination in which the unreacted epoxy ratio becomes 1.2% or less, and even more preferably a combination in which the unreacted epoxy ratio becomes 0.7% or less.

In the case where the resin composition for molding of the disclosure includes two or more types of epoxy resins or two or more types of active ester compounds, the resin composition for molding preferably includes at least one combination of the epoxy resin and the active ester compound in which the unreacted epoxy ratio becomes 2% or less.

As the epoxy resin, epoxy resins including sterically crowded structures in the molecule, such as triphenylmethane type epoxy resins having a structure in which three aryl groups are bonded to one carbon atom in the molecule, or epoxy resins containing substituents with large steric hindrance such as benzyl groups, tert-butyl groups, etc., as a substituent, tend to have unreacted epoxy groups remaining in the cured product due to steric hindrance when reacting with the active ester compound. With the unreacted epoxy groups remaining in the cured product, the strength of the cured product tends to decrease easily. Considering the above, in the disclosure, as the epoxy resin and the active ester compound, it is preferable to include a combination in which the unreacted epoxy ratio becomes 2% or less, more preferably a combination in which the unreacted epoxy ratio becomes 1.2% or less, and even more preferably a combination in which the unreacted epoxy ratio becomes 0.7% or less.

The anther epoxy resin and the active ester compound are preferably a combination in which the unreacted epoxy ratio becomes 2% or less, more preferably a combination in which the unreacted epoxy ratio becomes 1.2% or less, and even more preferably a combination in which the unreacted epoxy ratio becomes 0.7% or less. Since the specific novolac type epoxy resins do not include sterically crowded structures in the molecule, the specific novolac type epoxy resins tend to exhibit an unreacted epoxy ratio of 2% or less, and unreacted epoxy groups are less likely to occur during curing reaction with the active ester compound. Thus, the specific novolac type epoxy resins are less likely to cause a decrease in the strength of the cured product resulting from generation of unreacted epoxy groups.

In the disclosure, the unreacted epoxy ratio refers to a value measured according to the following method.

The epoxy resin and the active ester compound are weighed and mixed in an equivalent ratio of 1:1, and a phosphorus-based catalyst is added at 1 to 3 parts by mass with respect to 100 parts by mass of a total amount of the epoxy resin and the active ester compound, the mixture is melted and blended while heated on a hot plate at 130° C., and then cooled to room temperature and pulverized into a powder. The phosphorus-based catalyst is adjusted such that a gel time of the mixture of the epoxy resin and the active ester compound is about 60 seconds. The neat resin powder and a cured product sample after heating at 175° C. for 5.5 h are loaded in an FT-IR (Nicolet iZ10 manufactured by Thermo Fisher Scientific) apparatus, and absorption spectra are obtained. For each of them, an area ratio of an epoxy-derived peak (910 cm⁻¹) to an aromatic ring peak (1610 cm⁻¹) is calculated, and an unreacted portion of epoxy is quantified based on a rate of change in this ratio.

The gel time is measured according to the following method.

A test sample of 0.5 g is placed on a hot plate heated to 175° C., and using a jig, the sample is uniformly spread into a circular shape with a diameter of 2.0 cm to 2.5 cm at a rotational speed of 20 to 25 rotations per minute.

The time from when the test sample is placed on the hot plate until the test sample loses its viscosity, becomes in a gel state, and peels off from the hot plate is measured and is taken as the gel time (seconds).

### —Phenol Curing Agent—

The resin composition for molding of the disclosure may include a phenol curing agent as the another curing agent.

Specific examples of the phenol curing agent include: polyvalent phenol compounds such as resorcinol, catechol, bisphenol A, bisphenol F, substituted or unsubstituted biphenols, etc.; novolac type phenol resins obtained by condensation or co-condensation, under acidic catalysis, of at least one phenolic compound selected from the group consisting of phenol compounds such as phenol, cresol, xylenol, resorcinol, catechol, bisphenol A, bisphenol F, phenylphenol, aminophenol, etc., and naphthol compounds such as α-naphthol, β-naphthol, dihydroxynaphthalene, etc., with aldehyde compounds such as formaldehyde, acetaldehyde, propionaldehyde, etc.; aralkyl type phenol resins such as phenol aralkyl resins, naphthol aralkyl resins, etc. synthesized from the above phenolic compounds with dimethoxy paraxylene, bis(methoxymethyl)biphenyl, etc.; paraxylylene-modified phenol resins, metaxylylene-modified phenol resins; melamine-modified phenol resins; terpene-modified phenol resins; dicyclopentadiene type phenol resins and dicyclopentadiene type naphthol resins synthesized by copolymerization of the above phenolic compounds with dicyclopentadiene; cyclopentadiene-modified phenol resins; polycyclic aromatic ring-modified phenol resins; biphenyl type phenol resins; triphenylmethane type phenol resins obtained by condensation or co-condensation, under acidic catalysis, of the above phenolic compounds with aromatic aldehyde compounds such as benzaldehyde, salicylaldehyde, etc.; phenol resins obtained by copolymerization of two or more of the above; etc. These phenol curing agents may be used as one type alone or used as a combination of two or more types.

In the case where the resin composition for molding of the disclosure includes a phenol curing agent as the another curing agent, a melamine-modified phenol resin is preferable.

A hydroxyl equivalent of the phenol curing agent is not particularly limited. From the viewpoint of balancing various properties such as moldability, reflow resistance, electrical reliability, etc., the hydroxyl equivalent of the phenol curing agent is preferably 70 g/eq to 1000 g/eq, and more preferably 80 g/eq to 500 g/eq.

The hydroxyl equivalent of the phenol curing agent is a value measured according to a method conforming to JIS K 0070:1992.

An equivalent ratio between the epoxy resin and the curing agent, i.e., a ratio (number of functional groups in the curing agent/number of functional groups in the epoxy resin) of the number of functional groups in the curing agent to the number of functional groups in the epoxy resin, is not particularly limited. From the viewpoint of suppressing respective unreacted portions to lower levels, the equivalent ratio is preferably set to a range of 0.5 to 2.0, and more preferably set to a range of 0.6 to 1.3. From the viewpoint of moldability and reflow resistance, the equivalent ratio is even more preferably set to a range of 0.8 to 1.2.

In the case where an active ester compound and a phenol curing agent are used in combination as the curing agent, a molar ratio (ester groups/phenol hydroxyl groups) of the ester groups included in the active ester compound to the phenol hydroxyl groups included in the phenol curing agent is preferably 9/1 to 1/9, more preferably 8/2 to 2/8, and even more preferably 3/7 to 7/3.

In the case where an active ester compound and a phenol curing agent are used in combination as the curing agent, from the viewpoint of excellent flexural strength after curing the resin composition for molding and the viewpoint of suppressing the dielectric loss tangent of the cured product to a lower level, a mass ratio of the active ester compound in a total amount of the active ester compound and the phenol curing agent is preferably 40 mass % to 99 mass %, more preferably 60 mass % to 97 mass %, and even more preferably 80 mass % to 95 mass %.

Softening points or melting points of the active ester compound serving as the curing agent and the another curing agent such as a phenol curing agent used as necessary are not particularly limited. The softening point or the melting point of the curing agent is preferably 40° C. to 180° C. from the viewpoint of moldability and reflow resistance, and is more preferably 50° C. to 130° C. from the viewpoint of handling during manufacturing of the resin composition for molding.

The melting point or the softening point of the curing agent is a value measured in the same manner as the melting point or the softening point of the epoxy resin.

### (Inorganic Filler)

The resin composition for molding of the disclosure contains an inorganic filler. A type of the inorganic filler is not particularly limited. Specifically, examples thereof include silica such as fused silica, crystalline silica, etc., inorganic materials such as glass, alumina, aluminum nitride, boron nitride, talc, clay, mica, calcium titanate, barium titanate, etc. Inorganic fillers with flame retardant effects may also be used. Examples of inorganic fillers with flame retardant effects include aluminum hydroxide, magnesium hydroxide, composite metal hydroxides such as composite hydroxides of magnesium and zinc, zinc borate, etc.

Among the inorganic fillers, silica such as fused silica is preferable from the viewpoint of reducing the coefficient of linear expansion, and alumina is preferable from the viewpoint of high thermal conductivity. Boron nitride is preferable from the viewpoint of further reducing the dielectric loss tangent. The inorganic filler may be used as one type alone or used as a combination of two or more types. Examples of a form of the inorganic filler include a powder, a bead formed by spheroidizing the powder, a fiber, etc.

An average particle diameter of the inorganic filler is not particularly limited. For example, a volume average particle diameter is preferably 0.2 μm to 50 μm, and more preferably 0.5 μm to 30 μm.

With the volume average particle diameter being 0.2 μm or more, there is a tendency that an increase in viscosity of the resin composition for molding is further suppressed. With the volume average particle diameter being 50 μm or less, there is a tendency that a filling property into narrow gaps is further improved. The volume average particle diameter of the inorganic filler refers to a value measured as a volume average particle diameter (D50) by a laser diffraction scattering particle size distribution analyzer.

The volume average particle diameter of the inorganic filler in the resin composition for molding or the cured product thereof may be measured according to a conventional method. As an example, the inorganic filler is extracted from the resin composition for molding or the cured product using organic solvents, nitric acid, aqua regia, etc., and is sufficiently dispersed using an ultrasonic disperser or the like to prepare a dispersion. Using this dispersion, the volume average particle diameter of the inorganic filler may be measured from a volume-based particle size distribution measured by a laser diffraction scattering particle size distribution analyzer. Alternatively, the volume average particle diameter of the inorganic filler may be measured from a volume-based particle size distribution obtained by embedding the cured product in a transparent epoxy resin or the like, performing polishing to obtain a cross-section, and observing the cross-section with a scanning electron microscope. Furthermore, the volume average particle diameter may also be measured by continuously observing two-dimensional cross-sections of the cured product to perform three-dimensional structure analysis using an FIB device (focused ion beam SEM) and the like.

From the viewpoint of flowability of the resin composition for molding, a particle shape of the inorganic filler is preferably a spherical shape, which is more preferable than an angular shape, and the particle size distribution of the inorganic filler is preferably a distribution in a wide range.

From the viewpoint of controlling the flowability and strength of the cured product of the resin composition for molding, a content ratio of an entirety of the inorganic filler included in the resin composition for molding is preferably more than 50 volume %, more preferably more than 55 volume %, even more preferably more than 55 volume % and 90 volume % or less, and particularly preferably 60 volume % to 80 volume %, with respect to the entirety of the resin composition for molding.

The content ratio (volume %) of the inorganic filler in the resin composition for molding may be calculated according to the following method.

A thin slice sample of the cured product of the resin composition for molding is imaged using a scanning electron microscope (SEM). In the SEM image, any area S is specified, and a total area A of the inorganic filler included in the area S is calculated. A value obtained by dividing the total area A of the inorganic filler by the area S is converted to a percentage (%), and this value is taken as the content ratio (volume %) of the inorganic filler in the resin composition for molding.

The area S is an area sufficiently large compared to the size of the inorganic filler. For example, the area S is in a size in which 100 inorganic fillers or more are included. The area S may also be a sum of multiple cross-sections.

A bias for the inorganic filler may occur in a presence ratio in the gravity direction during curing of the resin composition for molding. In that case, when capturing images with the SEM, an entirety in the gravity direction of the cured product is imaged, and an area S in which the entirety in the gravity direction of the cured product is included is specified.

### (Release Agent)

From the viewpoint of obtaining good releasability from the mold during molding, the resin composition for molding of the disclosure may include a release agent. The release agent is not particularly limited, and conventional release agents may be used. Specifically, examples thereof include higher fatty acids such as carnauba wax, montanic acid, stearic acid, etc.; metal salts of higher fatty acids; ester-based waxes such as montanic acid esters; polyolefin-based waxes such as oxidized polyethylene, non-oxidized polyethylene, etc. The release agent may be used as one type alone or used as a combination of two or more types.

In the case where the resin composition for molding of the disclosure contains a release agent, a content of the release agent is preferably 1 part by mass to 30 parts by mass, more preferably 5 parts by mass to 25 parts by mass, and even more preferably 7 parts by mass to 20 parts by mass, with respect to 100 parts by mass of the epoxy resin. With the amount of the release agent being 1 part by mass or more with respect to 100 parts by mass of the epoxy resin, there is a tendency that releasability is sufficiently obtained. With the amount of the release agent being 30 parts by mass or less, there is a tendency that better bonding is obtained.

The content of the release agent is preferably 0.01 parts by mass to 10 parts by mass, and more preferably 0.1 parts by mass to 5 parts by mass, with respect to 100 parts by mass of a total of the epoxy resin and the curing agent. With the amount of the release agent being 0.01 parts by mass or more with respect to 100 parts by mass of the total of the epoxy resin and the curing agent, there is a tendency that releasability is sufficiently obtained. With the amount of the release agent being 10 parts by mass or less, there is a tendency that better bonding is obtained.

### (Curing Accelerator)

The resin composition for molding of the disclosure may include a curing accelerator as necessary. A type of the curing accelerator is not particularly limited and may be selected according to the type of the epoxy resin, desired properties of the resin composition for molding, etc.

Examples of the curing accelerator include: diazabicycloalkenes such as 1,5-diazabicyclo[4.3.0]non-5-ene (DBN), 1,8-diazabicyclo[5.4.0]undec-7-ene (DBU), etc.; cyclic amidine compounds such as 2-methylimidazole, 2-phenylimidazole, 2-phenyl-4-methylimidazole, 2-ethyl-4-methylimidazole, 2-heptadecylimidazole, etc.; derivatives of the above cyclic amidine compounds; phenol novolac salts of the above cyclic amidine compounds or derivatives thereof; compounds having intramolecular polarization formed by adding, to these compounds, compounds with n-bonds such as maleic anhydride, quinone compounds like 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, etc., and diazophenylmethane; cyclic amidinium compounds such as tetraphenylborate salt of DBU, tetraphenylborate salt of DBN, tetraphenylborate salt of 2-ethyl-4-methylimidazole, tetraphenylborate salt of N-methylmorpholine, etc.; tertiary amine compounds such as pyridine, triethylamine, triethylenediamine, benzyldimethylamine, triethanolamine, dimethylaminoethanol, tris(dimethylaminomethyl)phenol, etc.; derivatives of the above tertiary amine compounds; ammonium salt compounds such as tetra-n-butylammonium acetate, tetra-n-butylammonium phosphate, tetraethylammonium acetate, tetra-n-hexylammonium benzoate, tetrapropylammonium hydroxide, etc.; organic phosphines such as primary phosphines like ethylphosphine, phenylphosphine, etc., secondary phosphines like dimethylphosphine, diphenylphosphine, etc., tertiary phosphines like triphenylphosphine, diphenyl(p-tolyl)phosphine, tris(alkylphenyl)phosphine, tris(alkoxyphenyl)phosphine, tris(alkyl-alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylalylphosphine, alkyldiarylphosphine, trinaphthylphosphine, tris(benzyl)phosphine, etc.; phosphine compounds such as complexes of the above organic phosphines with organoborons; compounds having intramolecular polarization formed by adding compounds with π-bonds such as maleic anhydride, quinone compounds like 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, anthraquinone, etc., and diazophenylmethane, to the above organic phosphines or the above phosphine compounds; compounds having intramolecular polarization obtained through a dehydrohalogenation process after reacting, with the above organic phosphines or the above phosphine compounds, halogenated phenol compounds such as 4-bromophenol, 3-bromophenol, 2-bromophenol, 4-chlorophenol, 3-chlorophenol, 2-chlorophenol, 4-iodinated phenol, 3-iodinated phenol, 2-iodinated phenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, 4-bromo-4′-hydroxybiphenyl, etc.; tetrasubstituted phosphonium compounds such as tetrasubstituted phosphonium like tetraphenylphosphonium, tetraphenylborate salts of tetrasubstituted phosphonium like tetraphenylphosphonium tetra-p-tolylborate, salts of tetrasubstituted phosphonium with phenol compounds; salts of tetraalkylphosphonium with partial hydrolysates of aromatic carboxylic anhydrides; phosphobetaine compounds; adducts of phosphonium compounds with silane compounds, etc.

The curing accelerator may be used as one type alone or used as a combination of two or more types.

Specifically, the curing accelerator is preferably a curing accelerator including an organic phosphine. Examples of the curing accelerator including an organic phosphine include: the above organic phosphines; phosphine compounds such as complexes of the above organic phosphines with organoborons; compounds having intramolecular polarization formed by adding compounds with π-bonds to the above organic phosphines or the above phosphine compounds, etc.

Specifically, examples of particularly suitable curing accelerators include triphenylphosphine, adducts of triphenylphosphine with quinone compounds, adducts of tributylphosphine with quinone compounds, adducts of tri-p-tolylphosphine with quinone compounds, etc.

In the case where the resin composition for molding includes a curing accelerator, an amount thereof is preferably 0.1 parts by mass to 30 parts by mass, and more preferably 1 part by mass to 15 parts by mass, with respect to 100 parts by mass of the total of the epoxy resin and the curing agent. With the amount of the curing accelerator being 0.1 parts by mass or more with respect to 100 parts by mass of the total of the epoxy resin and the curing agent, there is a tendency for good curing in a short time. With the amount of the curing accelerator being 30 parts by mass or less with respect to 100 parts by mass of the total of the epoxy resin and the curing agent, there is a tendency that a good molded product is obtained without an overly high curing rate.

### (Stress Relief Agent)

The resin composition for molding of the disclosure may include a stress relief agent. By including a stress relief agent, occurrence of warpage deformation of a package and package cracking can be further reduced. Examples of the stress relief agent include conventional stress relief agents (flexible agents) generally used. Specifically, examples thereof include thermoplastic elastomers such as silicone-based, styrene-based, olefin-based, urethane-based, polyester-based, polyether-based, polyamide-based, polybutadiene-based thermoplastic elastomers, etc., indene-styrene-coumarone copolymers, organic phosphorus compounds such as triphenylphosphine oxide, phosphoric acid esters, etc., rubber particles such as natural rubber (NR), acrylonitrile-butadiene rubber (NBR), acrylic rubber, urethane rubber, silicone powder, etc., rubber particles having a core-shell structure such as methyl methacrylate-styrene-butadiene copolymer (MBS), methyl methacrylate-silicone copolymer, methyl methacrylate-butyl acrylate copolymer, etc. The stress relief agent may be used as one type alone or used as a combination of two or more types.

Examples of the silicone-based stress relief agent include silicone-based stress relief agents having an epoxy group, silicone-based stress relief agents having an amino group, silicone-based stress relief agents obtained by polyether-modifying the above, etc. Silicone compounds such as silicone compounds having an epoxy group, polyether-based silicone compounds, etc. are more preferable.

From the viewpoint of dielectric loss tangent, the stress relief agent preferably includes at least one of indene-styrene-coumarone copolymer and triphenylphosphine oxide.

In the case where the resin composition for molding includes a stress relief agent, an amount thereof is, for example, preferably 1 part by mass to 30 parts by mass, and more preferably 2 parts by mass to 20 parts by mass, with respect to 100 parts by mass of the total of the epoxy resin and the curing agent.

In the case where the stress relief agent includes at least one of indene-styrene-coumarone copolymer and triphenylphosphine oxide, the amount thereof is, for example, preferably 1 part by mass to 30 parts by mass, and more preferably 2 parts by mass to 20 parts by mass, with respect to 100 parts by mass of the total of the epoxy resin and the curing agent.

From the viewpoint of dielectric loss tangent, a content ratio of the silicone-based stress relief agent is preferably 20 mass % or less, more preferably 10 mass % or less, even more preferably 7 mass % or less, particularly preferably 5 mass % or less, and most preferably 0.5 mass % or less, with respect to the entirety of the resin composition for molding. A lower limit of the content ratio of the silicone-based stress relief agent is not particularly limited, and may be 0 mass %, or may be 0.1 mass %.

### [Various Additives]

In addition to the components described above, the resin composition for molding of the disclosure may also include various additives such as coupling agents, ion exchangers, flame retardants, colorants, etc., as exemplified below. The resin composition for molding of the disclosure may also include various conventional additives in the art as necessary, other than the additives exemplified below.

### (Coupling Agent)

The resin composition for molding of the disclosure may include a coupling agent. From the viewpoint of improving bonding of the inorganic filler with the epoxy resin and the curing agent, the resin composition for molding preferably includes a coupling agent. Examples of the coupling agent include conventional coupling agents such as silane-based compounds like epoxysilane, mercaptosilane, aminosilane, alkylsilane, ureidosilane, vinylsilane, disilazane, etc., titanium-based compounds, aluminum chelate-based compounds, aluminum/zirconium-based compounds, etc.

In the case where the resin composition for molding includes a coupling agent, an amount of the coupling agent is preferably 0.05 parts by mass to 5 parts by mass, and more preferably 0.1 parts by mass to 2.5 parts by mass, with respect to 100 parts by mass of the inorganic filler. With the amount of the coupling agent being 0.05 parts by mass or more with respect to 100 parts by mass of the inorganic filler, there is a tendency that bonding is further improved. With the amount of the coupling agent being 5 parts by mass or less with respect to 100 parts by mass of the inorganic filler, there is a tendency that moldability of a package is further improved.

### (Ion Exchanger)

The resin composition for molding of the disclosure may include an ion exchanger. From the viewpoint of improving moisture resistance and high-temperature storage properties of an electronic component device including a sealed electronic component, the resin composition for molding preferably includes an ion exchanger. The ion exchanger is not particularly limited, and conventional ion exchangers may be used. Specifically, examples thereof include hydrotalcite compounds, hydrous oxides of at least one element selected from the group consisting of magnesium, aluminum, titanium, zirconium, and bismuth, etc. The ion exchanger may be used as one type alone or used as a combination of two or more types. Specifically, hydrotalcite represented by General Formula (A) below is preferable.

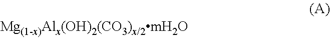

(0<X≤0.5, and m is a positive number)

In the case where the resin composition for molding includes an ion exchanger, a content thereof is not particularly limited as long as the amount is sufficient to capture ions such as halogen ions. For example, the content of the ion exchanger is preferably 0.1 parts by mass to 30 parts by mass, and more preferably 0.3 part by mass to 1 part by mass, with respect to 100 parts by mass of the total of the epoxy resin and the curing agent.

### (Flame Retardant)

The resin composition for molding of the disclosure may include a flame retardant. The flame retardant is not particularly limited, and conventional flame retardants may be used. Specifically, examples thereof include organic or inorganic compounds including halogen atoms, antimony atoms, nitrogen atoms, or phosphorus atoms, metal hydroxides, etc. The flame retardant may be used as one type alone or used as a combination of two or more types.

In the case where the resin composition for molding includes a flame retardant, an amount thereof is not particularly limited as long as the amount is sufficient to obtain a desired flame retardant effect. For example, the amount of the flame retardant is preferably 1 part by mass to 30 parts by mass, and more preferably 2 parts by mass to 20 parts by mass, with respect to 100 parts by mass of the total of the epoxy resin and the curing agent.

### (Colorant)

The resin composition for molding of the disclosure may include a colorant. Examples of the colorant include conventional colorants such as carbon black, organic dyes, organic pigments, titanium oxide, minium, red iron oxide, etc. A content of the colorant may be appropriately selected according to the purpose and the like. The colorant may be used as one type alone or used as a combination of two or more types.

### (Preparation Method of Resin Composition for Molding)

A preparation method of the resin composition for molding is not particularly limited. Examples of a general method may include a method in which components in predetermined formulation amounts are sufficiently mixed by a mixer or the like, and then are melt-kneaded by a mixing roll, an extruder, or the like, cooled, and pulverized. More specifically, examples may include a method in which predetermined amounts of the above components are stirred and mixed, kneaded by a kneader, a roll, an extruder, or the like preheated to 70° C. to 140° C., cooled, and pulverized.

The resin composition for molding of the disclosure is preferably a solid under normal temperature and pressure conditions (e.g., at 25° C. and atmospheric pressure). In the case where the resin composition for molding is a solid, a shape thereof is not particularly limited, and examples include forms of a powder, a granule, a tablet, etc. In the case where the resin composition for molding is in the form of a tablet, dimensions and a mass thereof are preferably configured to match molding conditions of the package, from the viewpoint of handling.

### (Properties of Resin Composition for Molding)

A relative permittivity at 5 GHz of the cured product of the resin composition for molding of the disclosure may be, for example, 2.5 to 4.0. From the viewpoint of miniaturization of the electronic component such as an antenna, the relative permittivity at 5 GHz of the cured product is preferably 2.6 to 3.7, more preferably 2.8 to 3.6, and even more preferably 2.9 to 3.5.

Measurement of the relative permittivity is performed at a temperature of 25±3° C. using a permittivity measuring apparatus (e.g., a cavity resonator).

A dielectric loss tangent at 5 GHz of the cured product of the resin composition for molding of the disclosure may be, for example, 0.008 or less. From the viewpoint of reducing transmission loss, the dielectric loss tangent at 5 GHz of the cured product is preferably 0.006 or less, more preferably 0.005 or less, and even more preferably 0.004 or less. A lower limit of the dielectric loss tangent at 5 GHz of the cured product is not particularly limited, and may be, for example, 0.001.

Measurement of the dielectric loss tangent is performed at a temperature of 25±3° C. using a permittivity measuring apparatus (e.g., a cavity resonator).

### (Applications of Resin Composition for Molding)

The resin composition for molding of the disclosure may be applied, for example, to manufacturing of electronic component devices to be described later, and among them, a high-frequency device in particular. The resin composition for molding of the disclosure may be used for sealing an electronic component in a high-frequency device.

In particular, in recent years, with the spread of the fifth-generation mobile communication system (5G), semiconductor packages (PKG) used in electronic component devices are becoming more advanced in functionality and smaller in size. Along with the miniaturization and functionality advancement of PKGs, development of an Antenna-in-Package (AiP), which is a PKG with an antenna function, is also progressing. In AiPs, to accommodate an increase in the number of channels due to diversification of information, radio waves used for communication are becoming higher in frequency, and sealing materials are required to have a low dielectric loss tangent.

As described above, the resin composition for molding of the disclosure yields a cured product with a low dielectric loss tangent. Thus, it is particularly suitable for Antenna-in-Package (AiP) applications, in which an antenna disposed on a supporting member is sealed with the resin composition for molding in high-frequency devices.

In an electronic component device including an antenna, such as an Antenna-in-Package, heat generation occurs due to power supply in the case where an amplifier for power supply is provided on the opposite side of the antenna. From the viewpoint of improving heat dissipation, the resin composition for molding used in manufacturing of the electronic component device preferably includes alumina particles as the inorganic filler.

### <Electronic Component Device>

The electronic component device of the disclosure includes a supporting member, an electronic component disposed on the supporting member, and a cured product of the above resin composition for molding that seals the electronic component.

Examples of the electronic component device include devices (e.g., high-frequency devices) obtained by mounting an electronic component (e.g., an active element such as a semiconductor chip, a transistor, a diode, a thyristor, etc.; a passive element such as a capacitor, a resistor, a coil, etc.; an antenna, etc.) on a supporting member such as a lead frame, a wired tape carrier, a wiring board, a glass, a silicon wafer, an organic substrate, etc., and sealing an obtained electronic component region with the resin composition for molding.

A type of the supporting member is not particularly limited, and supporting members generally used in manufacturing of electronic component devices may be used.

The electronic component may include an antenna, or may include an antenna and an element other than the antenna. The antenna is not particularly limited as long as it serves the role of an antenna, and may be an antenna element or a wiring.

Further, in the electronic component device of the disclosure, another electronic component may be disposed, as necessary, on a surface opposite to the surface on which the electronic component is disposed on the supporting member. The another electronic component may be sealed with the resin composition for molding, may be sealed with another resin composition, or may not be sealed.

### (Manufacturing Method of Electronic Component Device)

A manufacturing method of the electronic component device of the disclosure includes a process of disposing an electronic component on a supporting member, and a process of sealing the electronic component with the resin composition for molding described above.

Methods for implementing each of the above processes are not particularly limited, and may be performed according to general methods. Further, types of the supporting member and the electronic component used in manufacturing of the electronic component device are not particularly limited, and supporting members and electronic components generally used in manufacturing of electronic component devices may be used.

Examples of a method for sealing the electronic component using the resin composition for molding include low-pressure transfer molding, injection molding, compression molding, etc. Specifically, low-pressure transfer molding is a common method.

### Examples

Hereinafter, the embodiments will be specifically described based on Examples, but the scope of the embodiments is not limited to these Examples.

### <Preparation of Resin Composition for Molding>

Components shown below were mixed at 110° C. in formulation proportions (parts by mass) indicated in Table 1 to prepare resin compositions for molding of Examples and Comparative Examples. The resin composition for molding was a solid under normal temperature and pressure conditions.

Further, the content ratio of the inorganic filler (“Filler amount (volume %)” in the table) with respect to the entirety of the resin composition for molding is also shown in Table 1.
Epoxy resin 1 . . . Triphenylmethane type epoxy resin (epoxy equivalent: 169 g/eq)
Epoxy resin 2 . . . Triphenylmethane type epoxy resin (epoxy equivalent: 215 g/eq)
Epoxy resin 3: Biphenyl type epoxy resin (epoxy equivalent 192 g/eq)
Epoxy resin 4: Biphenyl aralkyl type epoxy resin (epoxy equivalent 274 g/eq)
Epoxy resin 5: o-Cresol novolac type epoxy resin (epoxy equivalent 200 g/eq)
Epoxy resin 6: Benzyl group-modified cresol novolac type epoxy resin (epoxy equivalent 264 g/eq)
Curing agent 1: Active ester compound, DIC Corporation, product name “EXB-8”
Curing agent 2: Melamine-modified phenol resin (hydroxyl equivalent: 120 g/eq)
Curing accelerator: Adduct of tributylphosphine and 1,4-benzoquinone
Coupling agent 1: N-phenyl-3-aminopropyltrimethoxysilane
Coupling agent 2: 3-Glycidoxypropyltrimethoxysilane
Coupling agent 3: 3-Methacryloxypropyltrimethoxysilane
Colorant: Carbon black
Ion exchanger: Hydrotalcite
Additive: Silicone oil with an epoxy equivalent of 2900 g/eq and a viscosity of 2850 mm²/s (25° C.)
Inorganic filler 1: Silica particle (volume average particle diameter 4.0 μm)
Inorganic filler 2: Silica particle (volume average particle diameter 0.5 μm)

The volume average particle diameter of each of the inorganic fillers is a value obtained according to the following measurement.

Specifically, first, the inorganic filler was added to a dispersion medium (water) in a range of 0.01 mass % to 0.1 mass %, and dispersed for 5 minutes using a bath-type ultrasonic cleaner.

5 ml of the obtained dispersion was injected into a cell, and a particle size distribution was measured at 25° C. using a laser diffraction scattering particle size distribution analyzer (LA920, manufactured by HORIBA, Ltd.).

A particle diameter at a cumulative value of 50% (volume basis) in the obtained particle size distribution was taken as the volume average particle diameter.

### (Evaluation of Spiral Flow (SF))

Using a mold for measuring a spiral flow in accordance with EMMI-1-66, the resin composition for molding was molded by a transfer molding machine under conditions of a mold temperature of 180° C., a molding pressure of 6.9 MPa, and a curing time of 120 seconds, and a flow distance (cm) was calculated. The results are shown in Table 1.

### (Evaluation of Flexural Strength)

The resin composition for molding was molded using a transfer molding machine under conditions of a molding temperature of 175° C., a molding pressure of 6.9 MPa, and a curing time of 120 seconds to obtain a plate-shaped molded product (127 mm in length, 12.7 mm in width, and 4 mm in thickness). This was taken as Test piece 1. Next, post-curing was performed on Test piece 1 at 175° C. for 5 hours to obtain a plate-shaped cured product (127 mm in length, 12.7 mm in width, and 4 mm in thickness). This was taken as Test piece 2.

A flexural strength (MPa) of Test piece 2 was measured using Autograph (bending test machine AG-500 manufactured by Shimadzu Corporation). The results are shown in Table 1.

### (Measurement of Relative Permittivity and Dielectric Loss Tangent)

The resin composition for molding was loaded into a transfer molding machine and molded under conditions of a mold temperature of 180° C., a molding pressure of 6.9 MPa, and a curing time of 120 seconds, and a post-curing was performed at 175° C. for 6 hours to obtain a rod-shaped cured product (90 mm in length, 0.6 mm in width, and 0.8 mm in thickness). Taking this cured product as a test piece, a relative permittivity (Dk) and a dielectric loss tangent (Df) at 5 GHz (model CP511) were measured at a temperature of 25±3° C. using a cavity resonator (Kanto Electronic Application & Development Co., Ltd.) and a network analyzer (Keysight Technologies, model name “PNA E8364B”). The results are shown in Table 1.

### (Measurement of Unreacted Epoxy Ratio)

Epoxy resin 1 to Epoxy resin 6 were used as the epoxy resin, Curing agent 1 was used as the curing agent, and the above curing accelerator was used as the phosphorus-based catalyst. Using these epoxy resin, curing agent, and curing accelerator, an unreacted epoxy ratio was measured according to the procedure described above. The obtained results are shown in Table 2.

TABLE 1

| | Comparative | Comparative | Example | Comparative | Comparative | Example | Comparative | Comparative |
|---|---|---|---|---|---|---|---|---|
| | Example 1 | Example 2 | 1 | Example 3 | Example 4 | 2 | Example 5 | Example 6 |
| Epoxy resin 1 | | 75.0 | | | 75.0 | | | |
| Epoxy resin 2 | | | | 75.0 | | | 75.0 | |
| Epoxy resin 3 | 25.0 | 25.0 | 25.0 | 25.0 | 25.0 | 25.0 | 25.0 | 25.0 |
| Epoxy resin 4 | 75.0 | | | | | | | |
| Epoxy resin 5 | | | 75.0 | | | 75.0 | | |
| Epoxy resin 6 | | | | | | | | 75.0 |
| Curing agent 1 | 86.0 | 122.0 | 108.0 | 91.9 | 110.0 | 96.9 | 89.8 | 77.7 |
| Curing agent 2 | | | | 5.8 | 6.9 | 6.1 | 6.9 | 6.0 |
| Curing accelerator | 4.5 | 3.2 | 3.5 | 2.8 | 2.4 | 2.4 | 2.8 | 2.9 |
| Coupling agent 1 | 5.0 | 5.0 | 5.0 | 5.0 | 5.0 | 5.0 | 5.0 | 5.0 |
| Coupling agent 2 | 1.0 | 1.0 | 1.0 | 1.0 | 1.0 | 1.0 | | |
| Coupling agent 3 | | | | | | | 3.0 | 3.0 |
| Colorant | 3.0 | 3.0 | 3.0 | 3.0 | 3.0 | 3.0 | 3.0 | 3.0 |
| Ion exchanger | | | | 1.0 | 1.0 | 1.0 | 1.0 | 1.0 |
| Additive | | | | 5.0 | 5.0 | 5.0 | 5.0 | 5.0 |
| Filler amount | 72 | 72 | 72 | 75 | 75 | 75 | 72 | 72 |
| (volume %) | | | | | | | | |
| Inorganic filler 1 | 796.0 | 932.0 | 878.0 | 1013.0 | 1090.0 | 1026.0 | 863.0 | 812.0 |
| Inorganic filler 2 | 199.0 | 233.0 | 220.0 | 253.0 | 272.0 | 257.0 | 216.0 | 203.0 |
| Total | 1194.5 | 1399.2 | 1318.5 | 1481.5 | 1596.3 | 1503.4 | 1295.5 | 1218.6 |
| SF (cm) | 153 | 132 | 139 | 134 | 98 | 125 | 188 | 209 |
| Flexural strength | 101 | 119 | 129 | 115 | 125 | 132 | 117 | 80 |
| Dk@5 GHz | 3.48 | 3.49 | 3.46 | 3.52 | 3.54 | 3.54 | 3.46 | 3.45 |
| Df@5 GHz | 0.0022 | 0.0023 | 0.0021 | 0.0049 | 0.0051 | 0.0046 | 0.0056 | 0.0057 |

TABLE 2

| | Epoxy | Epoxy | Epoxy | Epoxy | Epoxy | Epoxy |
|---|---|---|---|---|---|---|
| | resin 1 | resin 2 | resin 3 | resin 4 | resin 5 | resin 6 |
| Epoxy | 169 | 215 | 192 | 274 | 200 | 264 |
| equivalent | | | | | | |
| [g/eq] | | | | | | |
| Unreacted | 15 | 28 | 0.1 | 11.1 | 0.5 | 2.5 |
| epoxy ratio | | | | | | |
| [%] | | | | | | |

As clearly shown by the evaluation results in Table 1, it is learned that the cured product of the resin composition for molding of Example 1, which uses an active ester compound as the curing agent, exhibits a low dielectric loss tangent equivalent to that of the cured products of the resin compositions for molding of Comparative Example 1 and Comparative Example 2, and exhibits a higher bending strength.

Further, as clearly shown by the evaluation results in Table 1, it is learned that the cured product of the resin composition for molding of Example 2, which uses a combination of an active ester compound and a phenol resin as the curing agent, exhibits a lower dielectric loss tangent than the cured products of the resin compositions for molding of Comparative Example 3 and Comparative Example 4, and exhibits a higher flexural strength.

Although the resin compositions for molding of Comparative Example 5 and Comparative Example 6 contain slightly smaller filler amounts compared to the resin compositions for molding of Example 2, Comparative Example 3, and Comparative Example 4, the other components are approximately the same as those of the resin compositions for molding of Example 2, Comparative Example 3, and Comparative Example 4, except for the type of the epoxy resin. As clearly shown by the evaluation results in Table 1, it is learned that the cured product of the resin composition for molding of Example 2, which uses a combination of an active ester compound and a phenol resin as the curing agent, exhibits a lower dielectric loss tangent than the cured products of the resin compositions for molding of Comparative Example 5 and Comparative Example 6, and exhibits a higher flexural strength.

By using the specific novolac type epoxy resin as the curing agent, it becomes possible to form a cured product that exhibits a low dielectric loss tangent and is excellent in strength.

The disclosure of Japan Patent Application No. 2022-186881, filed on Nov. 22, 2022, is incorporated in its entirety herein by reference.

All literatures, patent applications, and technical standards described in this specification are cited herein to the same extent as the case where each literature, patent application, and technical standard is specifically and individually indicated to be incorporated by reference.

1. A resin composition for molding comprising: an epoxy resin containing at least one of a phenol novolac type epoxy resin with an epoxy equivalent of 156 g/eq to 250 g/eq and a cresol novolac type epoxy resin with an epoxy equivalent of 156 g/eq to 250 g/eq; an active ester compound; and an inorganic filler.

2. The resin composition for molding according to claim 1, comprising, as the epoxy resin and the active ester compound, a combination in which an unreacted epoxy ratio becomes 2% or less.

3. The resin composition for molding according to claim 1, wherein a content ratio of an entirety of the inorganic filler exceeds 50 volume % with respect to an entirety of the resin composition for molding.

4. The resin composition for molding according to claim 1, which is used for a high-frequency device.

5. The resin composition for molding according to claim 4, which is used for sealing an electronic component in the high-frequency device.

6. The resin composition for molding according to claim 4, which is used for an Antenna-in-Package.

7. An electronic component device comprising:
a supporting member;
an electronic component disposed on the supporting member; and
a cured product of the resin composition for molding according to claim 1, which seals the electronic component.

8. The electronic component device according to claim 7, wherein the electronic component comprises an antenna.
